(19) United States
(12) Patent Application Publication
(10) Pub. No.: US 2025/0311256 A1
(43) Pub. Date: Oct. 2, 2025

(54) SEMICONDUCTOR DEVICE

(71) Applicant: Samsung Electronics Co., Ltd., Suwon-si (KR)

(72) Inventors: Beomjin PARK, Suwon-si (KR); Myunggil KANG, Suwon-si (KR); Dongwon KIM, Suwon-si (KR); Donggwan SHIN, Suwon-si (KR); Hongseon YANG, Suwon-si (KR); Byeolhae EOM, Suwon-si (KR); Suhyeong CHA, Suwon-si (KR)

(73) Assignee: Samsung Electronics Co., Ltd., Suwon-si (KR)

(21) Appl. No.: 19/055,153

(22) Filed: Feb. 17, 2025

(30) Foreign Application Priority Data
Mar. 29, 2024 (KR) 10-2024-0043673

(51) Int. Cl. H10D 8/00; H10D 62/10

(52) U.S. Cl. CPC H10D 8/411; H10D 62/112; H10D 62/121; H10D 62/126

(57) ABSTRACT

A semiconductor device includes a substrate having a first surface and a second opposite surface, a pair of trench isolations penetrating through the substrate, and a first well region and a second well region in a first horizontal direction in the substrate between the pair of trench isolations, and contacting each other. The semiconductor device includes nanosheets and sacrificial dielectric patterns alternately stacked on the first and second well regions, a first inactive gate structure overlapping first ends of the nanosheets and the sacrificial dielectric patterns in a second horizontal direction, a second inactive gate structure overlapping second ends of the nanosheets and the sacrificial dielectric patterns, a first impurity region on the first well region and connected thereto, a second impurity region on the second well region and connected thereto, a first contact connected to the first impurity region, and a second contact connected to the second impurity region.

### CROSS-REFERENCE TO RELATED APPLICATION

This U.S. non-provisional application claims priority under 35 U.S.C. § 119 to Korean Patent Application No. 10-2024-0043673, filed on Mar. 29, 2024, in the Korean Intellectual Property Office, the disclosure of which is incorporated by reference herein in its entirety.

### BACKGROUND

Example embodiments of the inventive concepts relate to a semiconductor device including field effect transistors and diodes.

As the size of semiconductor devices gradually decreases, there is a need to increase the integration of field effect transistors on a substrate, and accordingly, a nanosheet field effect transistor (NSFET) including a plurality of nanosheets stacked on the same layout region has been developed. Recently, as the degree of integration of semiconductor devices has increased and the size of semiconductor devices has further decreased, there is a need to develop new structures that may improve the reliability of nanosheet field effect transistors and diodes with similar structures.

### SUMMARY

Example embodiments of the inventive concepts are directed to a semiconductor device including a lateral diode and provide improved performance and/or reliability.

According to some example embodiments of the inventive concepts, a semiconductor device includes a substrate having a first surface and a second surface opposite the first surface, a pair of trench isolations penetrating through the substrate, a first well region and a second well region in a first horizontal direction in the substrate between the pair of trench isolations, the first well region and the second well region contacting each other, a plurality of nanosheets and a plurality of sacrificial dielectric patterns alternately stacked in a vertical direction on the first well region and the second well region, a first inactive gate structure overlapping first ends of the plurality of nanosheets and the plurality of sacrificial dielectric patterns in a second horizontal direction perpendicular to the first horizontal direction, a second inactive gate structure overlapping second ends of the plurality of nanosheets and the plurality of sacrificial dielectric patterns in the second horizontal direction, the first ends and the second ends being opposite to each other in the first horizontal direction, a first impurity region on the first well region and connected thereto, the first impurity region penetrating through the plurality of nanosheets and the plurality of sacrificial dielectric patterns in the vertical direction, a second impurity region on the second well region and connected thereto, the second impurity region penetrating through the plurality of nanosheets and the plurality of sacrificial dielectric patterns in the vertical direction, a first contact connected to the first impurity region, and a second contact connected to the second impurity region.

According to some example embodiments of the inventive concepts, a semiconductor device includes a substrate having a first surface and a second surface opposite the first surface, a pair of trench isolations penetrating the substrate and spaced from each other in a first horizontal direction, a plurality of nanosheets and a plurality of sacrificial dielectric patterns alternately stacked in a vertical direction on the substrate between the pair of trench isolations, a first inactive gate structure overlapping first ends of the plurality of nanosheets and the plurality of sacrificial dielectric patterns in a second horizontal direction perpendicular to the first horizontal direction, a second inactive gate structure overlapping second ends of the plurality of nanosheets and the plurality of sacrificial dielectric patterns in the second horizontal direction, the first ends and the second ends being opposite to each other in the first horizontal direction, a first impurity region penetrating the substrate, the plurality of nanosheets, and the plurality of sacrificial dielectric patterns in the vertical direction, a second impurity region penetrating the substrate, the plurality of nanosheets, and the plurality of sacrificial dielectric patterns in the vertical direction, a first contact connected to the first impurity region, and a second contact connected to the second impurity region.

According to some example embodiments of the inventive concepts, a semiconductor device includes a substrate having a first surface and a second surface opposite the first surface, a pair of trench isolations penetrating the substrate, a first well region and a second well region in a first horizontal direction in the substrate between the pair of trench isolations, the first well region and the second well region contacting each other, a plurality of nanosheets and a plurality of sacrificial dielectric patterns alternately stacked in a vertical direction on the first well region and the second well region, a first impurity region penetrating through the plurality of nanosheets and the plurality of sacrificial dielectric patterns in the vertical direction on the first well region, the first impurity region contacting the first well region, a second impurity region penetrating through the plurality of nanosheets and the plurality of sacrificial dielectric patterns in the vertical direction on the second well region, the second impurity region contacting the second well region, a first contact connected to the first impurity region, a second contact connected to the second impurity region, and a back side power distribution network beneath the second surface of the substrate.

### BRIEF DESCRIPTION OF THE DRAWINGS

For a more complete understanding of this disclosure, reference is now made to the following brief description, taken in connection with the accompanying drawings and detailed description, wherein like reference numerals represent like parts.

FIG. 1A is a plan view showing components of a semiconductor device, according to some example embodiments.

FIG. 1B is a cross-sectional view taken along line B-B′ in FIG. 1A.

FIG. 2A is a plan view showing components of a semiconductor device, according to some example embodiments.

FIG. 2B is a cross-sectional view taken along line B-B′ in FIG. 2A.

FIG. 3A is a plan view of a semiconductor device, according to some example embodiments.

FIG. 3B is a plan view of another semiconductor device, according to some example embodiments.

FIG. 4 is a cross-sectional view of a semiconductor device, according to some example embodiments.

FIGS. 5, 6, 7, 8, 9, 10, 11, 12, 13, and 14 are cross-sectional views illustrating operations in a method of manufacturing a semiconductor device, according to some example embodiments.

FIGS. 15, 16, 17, 18, 19, 20, 21, 22, and 23 are cross-sectional views illustrating operations in a method of manufacturing a semiconductor device, according to some example embodiments.

FIG. 24 illustrates a configuration of a system including a semiconductor device, according to some example embodiments.

### DETAILED DESCRIPTION

As used herein, the term “and/or” includes any and all combinations of one or more of the associated listed items. Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C,” “at least one of A, B, or C”) may be construed as A only, B only, C only, or any combination of two or more of A, B, and C, such as, for instance, ABC, AB, BC, and AC.

It will be understood that elements and/or properties thereof may be recited herein as being “the same” or “equal” as other elements, and it will be further understood that elements and/or properties thereof recited herein as being “identical” to, “the same” as, or “equal” to other elements may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to and/or the same or substantially the same as other elements and/or properties thereof may be structurally the same or substantially the same, functionally the same or substantially the same, and/or compositionally the same or substantially the same. While the term “same,” “equal” or “identical” may be used in description of some example embodiments, it should be understood that some imprecisions may exist. Thus, when one element, value, and/or property is referred to as being the same as another element, value, and/or property, it should be understood that an element, value, and/or property is the same as another element, value, and/or property within a desired manufacturing or operational tolerance range (e.g., +10%).

When the terms “about” or “substantially” are used in this specification in connection with a numerical value, it is intended that the associated numerical value includes a manufacturing or operational tolerance (e.g., +10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., +10%) around the stated numerical values or shapes. When ranges are specified, the range includes all values therebetween such as increments of 0.1%.

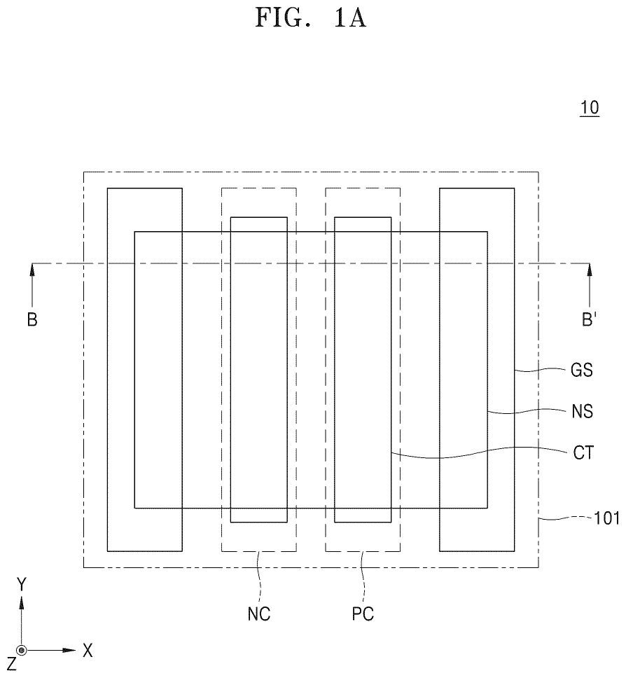

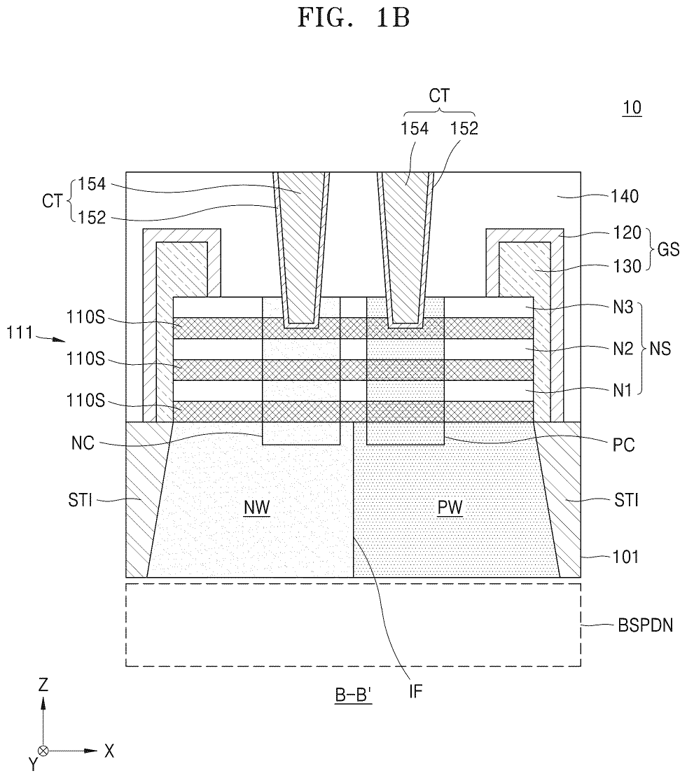

FIG. 1A is a plan view showing components of a semiconductor device 10, according to some example embodiments. FIG. 1B is a cross-sectional view taken along line B-B′ in FIG. 1A.

Referring to FIGS. 1A and 1B, the semiconductor device 10 may include a lateral diode formed on a substrate 101. The substrate 101 may include a wafer including silicon (Si). In some example embodiments, the substrate 101 may be or include a semiconductor material, such as germanium (Ge), or a compound semiconductor material, such as silicon carbide (SiC), gallium arsenide (GaAs), indium arsenide (InAs), indium phosphide (InP), a combination thereof, or the like. In some example embodiments, the substrate 101 may have a silicon on insulator (SOI) structure.

A pair of trench isolations STI may be disposed on the substrate 101 to partition (or isolate) a region where the lateral diode is formed. In some example embodiments, each trench isolation STI may be a shallow trench isolation that extends through the substrate 101. The trench isolation STI may have a double-layer structure including an interface layer and a buried dielectric layer.

In addition, and as illustrated, the substrate 101 may include a first well region NW and a second well region PW disposed in a first horizontal direction (X direction) between the pair of trench isolations STI and contacting each other (e.g., directly contacting each other along the Y direction). Each of the first well region NW and the second well region PW may be formed using a doping process. For example, the first well region NW is a region doped with an impurity having a first conductivity type, and the second well region PW is a region doped with an impurity having a second conductivity type different from the first conductivity type. Here, the first conductivity type may be n-type, and the second conductivity type may be p-type, but are not limited thereto. Accordingly, the first well region NW may be referred to as an n-type well, and the second well region PW may be referred to as a p-type well.

In the semiconductor device 10 of the inventive concepts, a lateral PN junction diode may be formed through a contact interface IF where the first well region NW and the second well region PW contact each other. Also, the semiconductor device 10 may include a gate structure GS that may be vertically offset (or otherwise, misaligned) from the contact interface IF. In some example embodiments, and as illustrated, the gate structure GS is not directly over the contact interface IF. Stated differently, gate structure GS does not directly overlap the contact interface IF.

In some example embodiments, the substrate 101 including the first well region NW and the second well region PW may be planarized (e.g., to reduce a thickness (Z direction) of the substrate 101) such that upper (or top) surfaces of the first well region NW and the second well region PW may be substantially at a same level as an upper (or top) surface of the substrate 101, and lower (or bottom) surfaces of the first well region NW and the second well region PW may be substantially at a same level as the lower (or bottom) surface of the substrate 101.

A plurality of nanosheets N1, N2, N3 (collectively referred to as nanosheets NS) and a plurality of sacrificial dielectric patterns 110S may form a stacked structure 111 that includes the plurality of nanosheets NS and the plurality of sacrificial dielectric patterns 110S stacked alternately in a vertical direction (Z direction) on the first well region NW and the second well region PW.

In some example embodiments, the nanosheets NS may be spaced apart from each other in the vertical direction (Z direction), and adjacent nanosheets NS (e.g., nanosheets N1 and N2) may include a sacrificial dielectric patterns 110S therebetween. Each of the nanosheets NS may include a semiconductor element (such as Si or Ge), or a compound semiconductor (such as SiC, GaAs, InAs, or InP), equivalents thereof, and the like.

In some example embodiments, each nanosheet NS may be a sheet-like structure having a semiconductor pattern and that has a width in the first horizontal direction (X direction) greater than a thickness in the vertical direction (Z direction). For example, each of the nanosheets NS may have a width in the first horizontal direction (X direction) in a range from about 5 nm to about 100 nm, and a thickness in the vertical direction (Z direction) in a range from about 1 nm to about 10 nm. However, example embodiments are not limited thereto and the width and thickness of the nanosheets NS may be varied as required by design and application. In some example embodiments, at least one nanosheet (e.g., N1, N2, N3) among the plurality of nanosheets NS may have a different thickness in the vertical direction (Z direction) from the remaining nanosheets NS.

Although, FIG. 1B illustrates 3 nanosheets N1, N2, and N3 spaced apart from each other in the vertical direction (Z direction), it will be understood that the number of nanosheets NS is not limited thereto and may be increased or decreased as required by application and design. In the semiconductor device 10, according to some example embodiments, the nanosheets NS may form a part of a lateral diode.

In the semiconductor device 10, according to some example embodiments, the sacrificial dielectric patterns 110S may be disposed between the nanosheets NS. The plurality of sacrificial dielectric patterns 110S include dielectric patterns. The sacrificial dielectric patterns 110S may constitute a portion of a lateral diode. Although, FIG. 1B illustrates 3 sacrificial dielectric patterns 110S spaced apart from each other in the vertical direction (Z direction), it will be understood that the number of sacrificial dielectric patterns 110S is not limited thereto and may be increased or decreased as required by application and design.

In some example embodiments, the width of the nanosheets NS in the first horizontal direction (X direction) and a width of the sacrificial dielectric patterns 110S in the first horizontal direction (X direction) may be substantially the same. In some example embodiments, ends of the nanosheets NS in the first horizontal direction (X direction) and each end of the pair of trench isolations STI on the upper surface of the substrate 101 may coincide (or otherwise align with each other) in the vertical direction (Z direction).

The semiconductor device 10 may include a gate structure GS disposed on each of the opposite ends of the nanosheets NS and the sacrificial dielectric patterns 110S in the first horizontal direction (X direction). Each gate structure GS may extend along and overlap (e.g., entirely) the edges of the nanosheets NS and the sacrificial dielectric patterns 110S in a second horizontal direction (Y direction). Each gate structure GS may also partially overlap the edges of the nanosheets NS and the sacrificial dielectric patterns 110S in the first horizontal direction (X direction). The gate structure GS shown in FIGS. 1A and 1B may be referred to as an inactive gate structure or a dummy gate structure. This is in contrast to an “active gate structure” or a “functional gate structure” that refers to a gate structure used to control output current (i.e., flow of carriers in the channel) of a semiconducting device. The gate structure GS may not be used to control output current of (or otherwise operate) the semiconductor device 10.

The gate structure GS may include a gate spacer 120 and a gate electrode 130 surrounded by the gate spacer 120. In some example embodiments, the gate spacer 120 may include silicon oxide, silicon nitride, silicon oxynitride, silicon carbonitride, silicon oxycarbonitride, or any combination thereof. In some example embodiments, the gate electrode 130 may include doped polysilicon, metal, conductive metal nitride, conductive metal carbide, conductive metal silicide, or any combination thereof. For example, the gate electrode 130 may include Al, Cu, Ti, Ta, W, Mo, TaN, NiSi, CoSi, TiN, WN, TiAl, TiAlN, TaCN, TaC, TaSiN, or any combination thereof.

The semiconductor device 10 may include, on the first well region NW, a first impurity region NC that is electrically connected to the first well region NW and penetrates through the nanosheets NS and the sacrificial dielectric patterns 110S in the vertical direction (Z direction). The semiconductor device 10 may include, on the second well region PW, a second impurity region PC that is electrically connected to the second well region PW and penetrates through the nanosheets NS and the sacrificial dielectric patterns 110S in the vertical direction (Z direction). The first impurity region NC and the second impurity region PC, as illustrated in FIGS. 1A and 1B, may form a portion of a lateral diode.

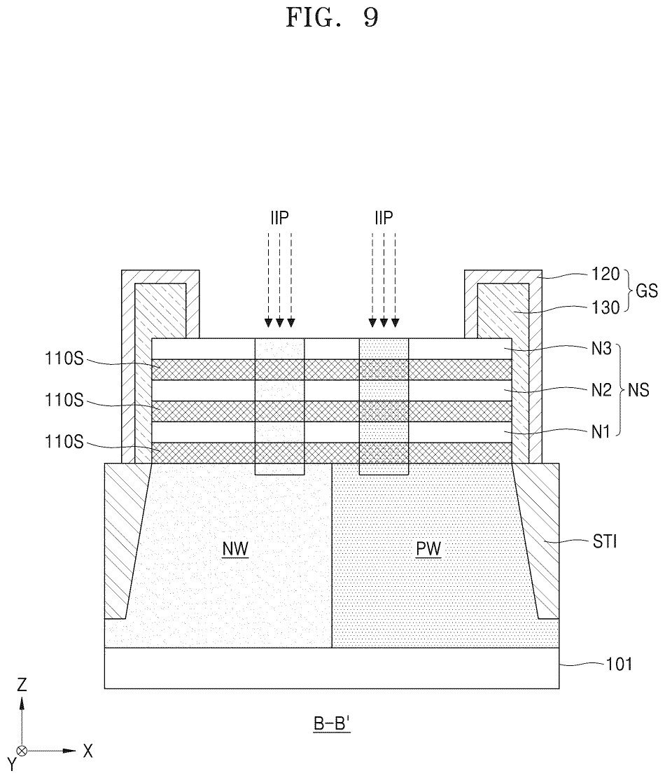

The first impurity region NC and the second impurity region PC may electrically connect the first well region NW and the second well region PW to contacts CT. Accordingly, the first impurity region NC may include the same conductivity type impurity (e.g., n-type impurity) as the first well region NW, and the second impurity region PC may include the same conductivity type impurity (e.g., p-type impurity) as the second well region PW. As described with reference to FIG. 9, the first impurity region NC and the second impurity region PC may be formed using an ion implantation process and a heat treatment process, for instance, and may have a predetermined conductivity type and a predetermined depth.

In some example embodiments, upper (or top) surfaces of the first impurity region NC and the second impurity region PC may be at substantially the same level (in the Z direction) as an upper (or top) surface of the third nanosheet N3 (or the topmost nanosheet of the plurality of nanosheets NS). In some example embodiments, lowermost (or bottom) surfaces of the first impurity region NC and the second impurity region PC may be located inside the substrate 101 a certain depth from an upper surface of the substrate 101.

An inter-gate dielectric layer 140 may be disposed to cover the pair of gate structures GS and nanosheets NS. The inter-gate dielectric layer 140 may include silicon oxide, silicon nitride, silicon oxynitride, silicon carbonitride, silicon oxycarbonitride, or any combination thereof.

The contacts CT may be formed through the inter-gate dielectric layer 140 and into the third nanosheet N3 (or the topmost nanosheet of the plurality of nanosheets NS) and a portion of the sacrificial dielectric patterns 110S below the third nanosheet N3 (and directly contacting thereto). The contacts CT may include a first contact electrically connected to the first impurity region NC and a second contact electrically connected to the second impurity region PC. The contacts CT may be disposed between the pair of gate structures GS in the first horizontal direction (X direction).

In some example embodiments, each of the contacts CT may be formed in a double-layer structure including a metal buried layer 154 and a metal barrier film 152 surrounding side and bottom surfaces of the metal buried layer 154. In other words, the metal barrier film 152 may be first disposed to contact the third nanosheet N3 and a portion of the sacrificial dielectric patterns 110S, and the metal buried layer 154 may be disposed over and covering the metal barrier film 152. In other embodiments, the metal barrier film 152 may be omitted, and the contact CT may be formed as a single layer structure including the metal buried layer 154.

In some example embodiments, the metal barrier film 152 may include, for example, titanium (Ti), tantalum (Ta), ruthenium (Ru), titanium nitride (TiN), tantalum nitride (TaN), or any combination thereof. In some example embodiments, the metal buried layer 154 may include at least one of cobalt (Co), tungsten (W), nickel (Ni), ruthenium (Ru), copper (Cu), aluminum (Al), silicides thereof, or alloys thereof. However, the metal barrier film 152 and the metal buried layer 154 are not limited thereto.

A back-end-of-line (BEOL) structure may be disposed on the inter-gate dielectric layer 140 and the contacts CT. The BEOL structure may include vias connected to contacts CT and metal wires connected to the vias.

As electronic technology develops, down-scaling of semiconductor devices is rapidly progressing. Down-scaled semiconductor devices require not only faster operating speed, but also higher operation accuracy. In some example embodiments, the semiconductor device 10 may further include a backside power delivery network (BSPDN), which is a wiring structure that provides faster operating speed and higher operational accuracy within a relatively small area.

In the semiconductor device 10 of the inventive concepts, a BSPDN may be formed on a lower surface of the substrate 101. Alternatively, a connection structure such as a via contact for connecting the BSPDN structure and a lateral diode and/or nanosheet field effect transistor may further be formed.

An inactive gate structure may be formed on a contact interface of a diode. Due to the presence of the inactive gate structure, a band-to-band tunneling effect occurs due to the gate electrode (metal material) of the inactive gate structure, and may result in leakage current in the semiconductor device.

In the semiconductor device 10, according to inventive concepts, the first impurity region NC and the second impurity region PC are formed in a lateral PN junction diode (e.g., a diode including the first well region NW and the second well region PW), and the gate structure GS is vertically offset from the contact interface IF. By forming the gate structure GS offset from the contact interface IF, band-to-band tunneling effect occurring due to the gate electrode is minimized, and leakage current is reduced. Thus, the performance and reliability of the semiconductor device 10 is improved.

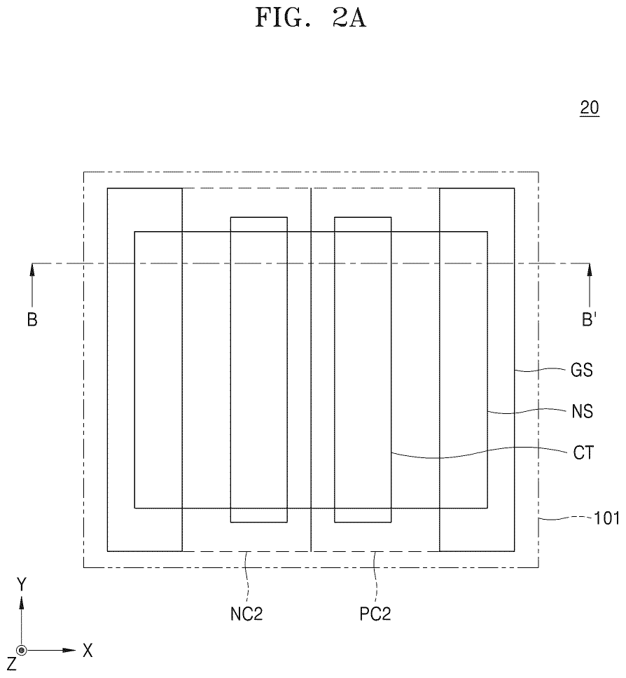

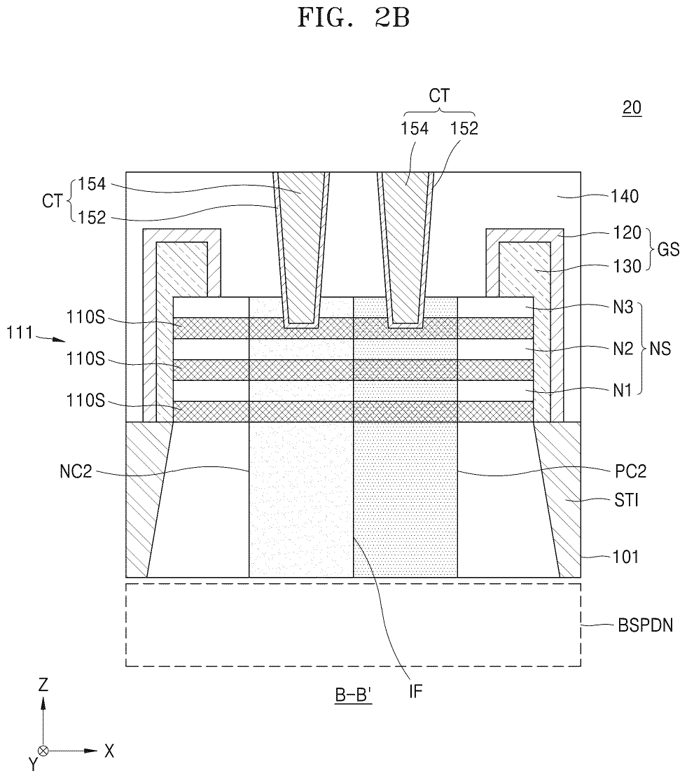

FIG. 2A is a plan view showing components of a semiconductor device 20, according to some example embodiment. FIG. 2B is a cross-sectional view taken along line B-B′ in FIG. 2A.

The semiconductor device 20 may be similar in some respects to the semiconductor device 10 of FIGS. 1A and 1B, and therefore may be best understood with reference thereto where like numerals indicate like elements not described again in detail.

Referring to FIGS. 2A and 2B, the semiconductor device 20 of the inventive concepts may include a lateral diode including a first impurity region NC2 and a second impurity region PC2.

In the semiconductor device 20, the first well region NW and the second well region PW may be absent. The semiconductor device 20 include the substrate 101, a plurality of nanosheets NS, and the first impurity region NC2 and the second impurity region PC2. The first impurity region NC2 and the second impurity region PC2 penetrate (or are formed in) the plurality of sacrificial dielectric patterns 110S in the vertical direction (Z direction) and contact each other.

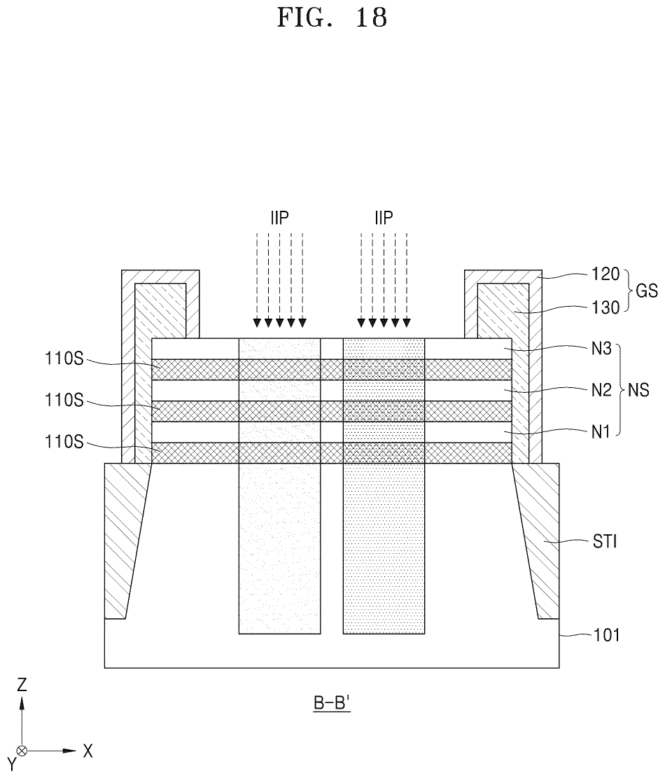

The first impurity region NC2 and the second impurity region PC2 may be doped with impurities of different conductivity types. In some example embodiments, the first impurity region NC2 may include an n-type impurity, and the second impurity region PC2 may include a p-type impurity. As described with reference to FIG. 18, the first impurity region NC2 and the second impurity region PC2 may be formed using an ion implantation process and a heat treatment process, for instance, and may have a predetermined conductivity type and a predetermined depth.

Accordingly, a lateral PN junction diode may be formed through a contact interface IF where the first impurity region NC2 and the second impurity region PC2 contact each other. The contact interface IF may be formed across the substrate 101, the nanosheets NS, and the sacrificial dielectric patterns 110S. As illustrated, the gate structure GS may be formed vertically offset from the contact interface IF.

The upper (or top) surfaces of the first impurity region NC2 and the second impurity region PC2 may be substantially at a same level as an upper (or top) surface of a third nanosheet N3 (or the topmost nanosheet). In some example embodiments, the lowermost (or bottom) surfaces of the first impurity region NC2 and the second impurity region PC2 are substantially at a same level as the lowermost (or bottom) surface of the substrate 101.

The semiconductor device 20 may include contacts CT formed through the inter-gate dielectric layer 140 and into the third nanosheet N3 and the sacrificial dielectric patterns 110S. The contacts CT may include a first contact electrically connected to the first impurity region NC2 and a second contact electrically connected to the second impurity region PC2. The contacts CT may be disposed between a pair of gate structures GS in the first horizontal direction (X direction).

In the semiconductor device 20, the first impurity region NC2 and the second impurity region PC2 form the lateral PN junction diode, and the gate structure GS is vertically offset from the contact interface IF of the lateral PN junction diode. By forming the gate structure GS offset from the contact interface IF, band-to-band tunneling effect occurring due to the gate electrode is limited, and leakage current is reduced. Thus, the performance and reliability of the semiconductor device 20 is improved.

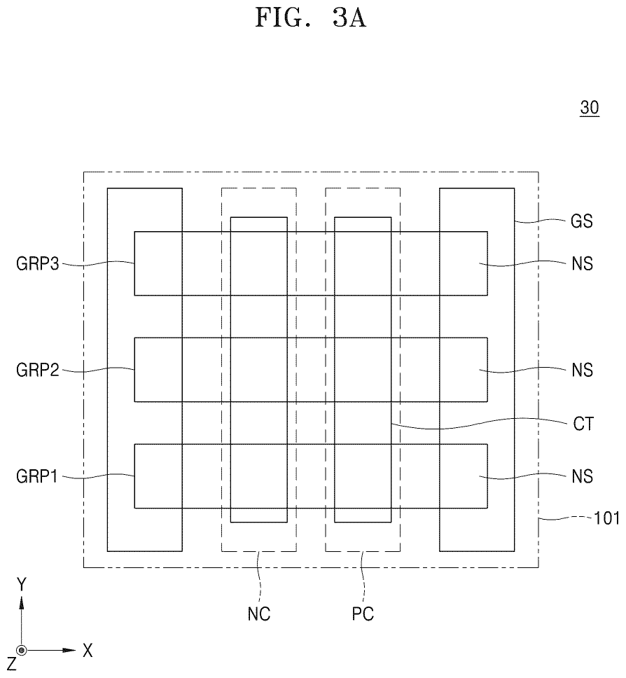

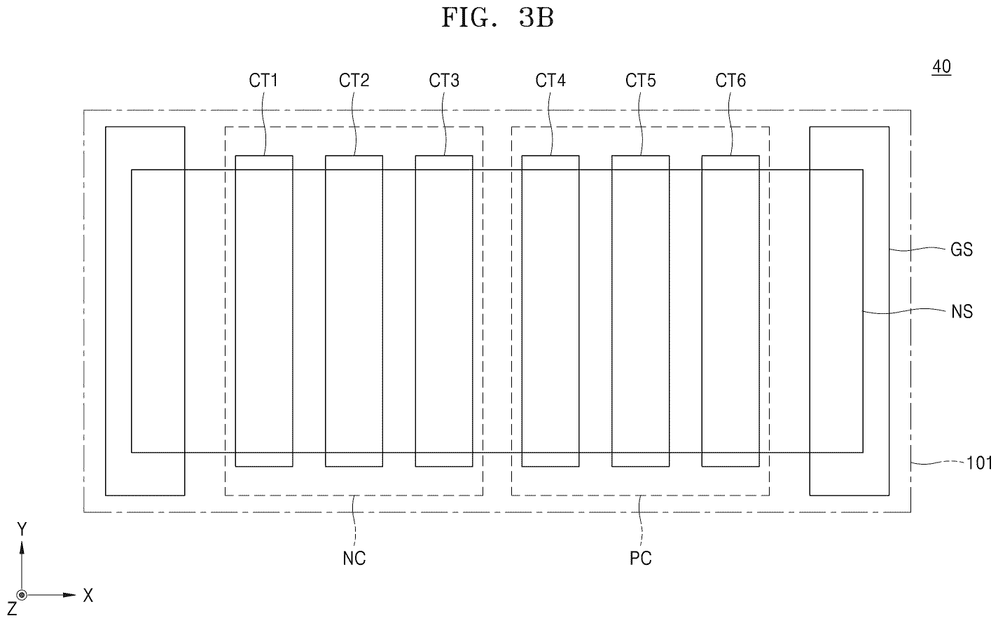

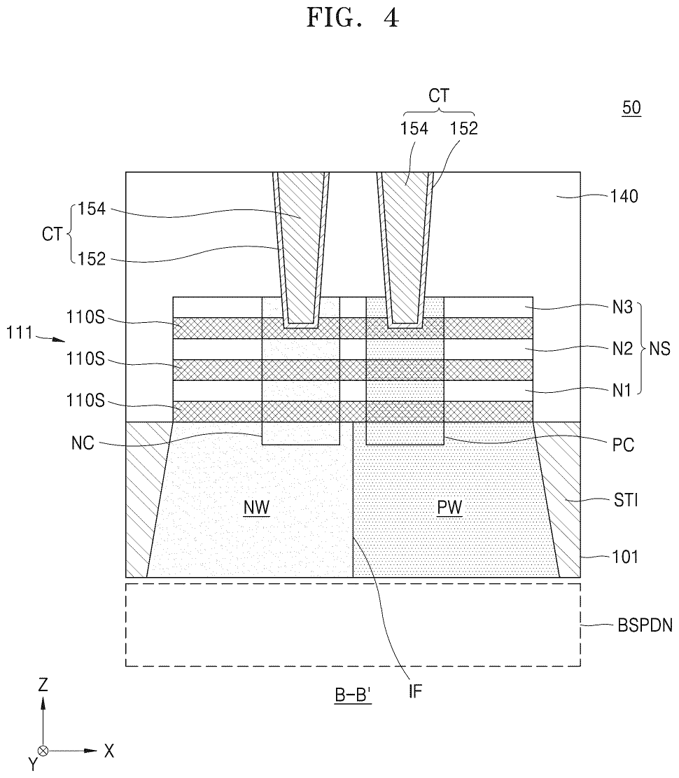

FIGS. 3A, and 3B are schematic plan views of semiconductor devices 30 and 40, according to some example embodiments. FIG. 4 is a cross-sectional view of a semiconductor device 50, according to some example embodiments.

The semiconductor devices 30, 40, and 50 may be similar in some respects to the semiconductor devices 10 and 20 of FIGS. 1A, 1B, 2A, and 2B, and therefore may be best understood with reference thereto where like numerals indicate like elements not described again in detail.

Referring to FIG. 3A, in the semiconductor device 30, the plurality of nanosheets NS and the plurality of sacrificial dielectric patterns may be formed on a substrate 101 as multiple groups GRP1, GRP2, and GRP3 (collectively groups GRP) with each group including a plurality of nanosheets NS and a plurality of the sacrificial dielectric patterns. Each group GRP1, GRP2, and GRP3 of nanosheets and sacrificial dielectric patterns are spaced apart from each other in a second horizontal direction (Y direction) perpendicular to the first horizontal direction (X direction). It will be understood that the number of groups is not limited to 3, and the semiconductor device 30 may include 2 groups of nanosheets or more than 3 groups of nanosheets.

In the semiconductor device 30, the nanosheets NS in the groups GRP may be formed in a multi fin type in which the nanosheets NS are spaced apart from each other in the second horizontal direction (Y direction) and each nanosheet consists of a plurality of fins type extending in the second horizontal direction (Y direction).

Referring to FIG. 3B, in the semiconductor device 40, each of the first impurity region NC and the second impurity region PC may include a plurality of contacts CT. The plurality of contacts CT may be disposed between a pair of gate structures GS in the first horizontal direction (X direction). Each of the plurality of contacts CT may be electrically connected to the respective first impurity region NC and second impurity region PC. For instance, as illustrated in FIG. 3B, the first impurity region NC may include contacts CT1, CT2, and CT3 and the second impurity region PC may include contacts CT4, CT5, and CT6. It will be understood that the number of contacts is not limited to 3, and each of the first impurity region NC and the second impurity region PC may include 2 contacts or more than 3 contacts. In addition, or alternatively, the number of contacts on the first impurity region NC and the second impurity region PC may be different. For instance, region NC may include 3 contacts, while the region PC may include 4 or more contacts.

Referring to FIG. 4, in the semiconductor device 50, an inactive gate structure (or dummy gate structure) GS may not be formed at opposite ends (in X direction) of the nanosheets NS and the sacrificial dielectric patterns 110S. Accordingly, opposite ends of the nanosheets NS and the sacrificial dielectric patterns 110S may contact the inter-gate dielectric layer 140. For instance, the ends of the nanosheets NS and the sacrificial dielectric patterns 110S extending along the Y direction may directly contact the inter-gate dielectric layer 140. Similarly, the ends of the nanosheets NS and the sacrificial dielectric patterns 110S extending along the X direction and overlapped by the inactive gate structure GS (FIGS. 1A, 1B) may directly contact the inter-gate dielectric layer 140.

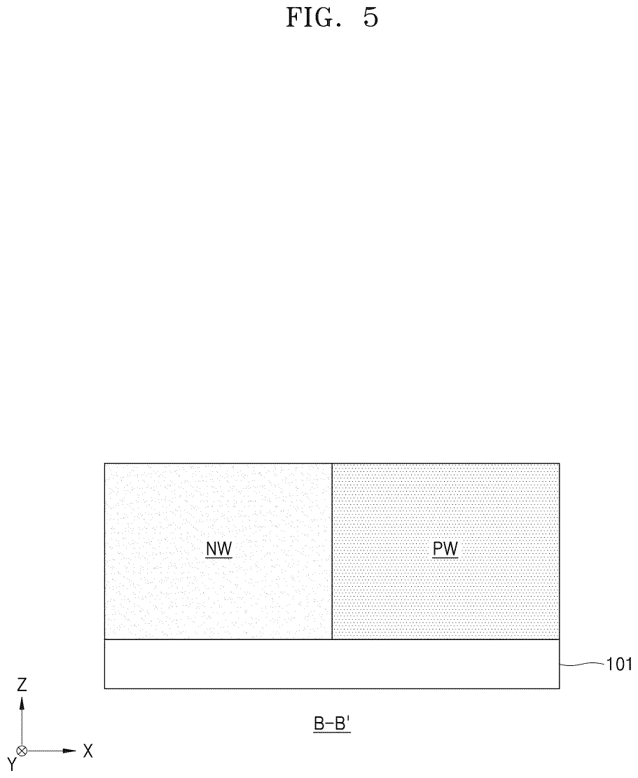

FIGS. 5 to 14 are cross-sectional views illustrating operations in a method of manufacturing a semiconductor device, according to some example embodiments. It is understood that additional operations can be provided before, during, and after the operations in FIGS. 5-14, and some of the operations described below can be replaced or eliminated, for additional embodiments of the method. The order of the operations/processes may be interchangeable, or two or more operations can be performed simultaneously.

Referring to FIG. 5, a substrate 101 having a first surface and a second surface opposite the first surface may be prepared. The first surface may correspond to an upper surface (or active surface) of the substrate 101 and a second surface may correspond to a lower surface (or inactive surface) of the substrate 101. A first well region NW and a second well region PW that contact each other may be formed on the substrate 101. Each of the first well region NW and the second well region PW may be formed using a doping process. For example, the first well region NW may be a region doped with a first conductivity type impurity, and the second well region PW may be a region doped with a second conductivity type impurity. In some example embodiments, the first conductivity type may be an n-type, and the second conductivity type may be a p-type, but are not limited thereto.

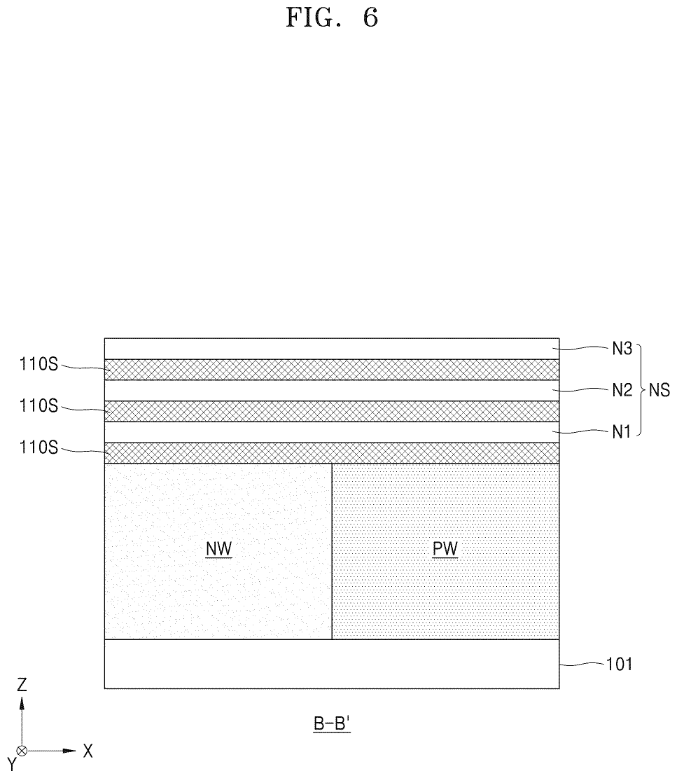

Referring to FIG. 6, nanosheets NS and sacrificial dielectric patterns 110S may be alternately stacked in the vertical direction (Z direction) on the upper surface of the substrate 101. Each of the nanosheets NS may be a semiconductor pattern. In some example embodiments, the nanosheets NS may include a first nanosheet N1, a second nanosheet N2, and a third nanosheet N3 spaced apart in the vertical direction (Z direction). The sacrificial dielectric patterns 110S may be formed between the nanosheets NS. In some example embodiments, a width (or length) of the nanosheets NS in the first horizontal direction (X direction) and a width (or length) of the sacrificial dielectric patterns 110S in the first horizontal direction (X direction) may be substantially equal.

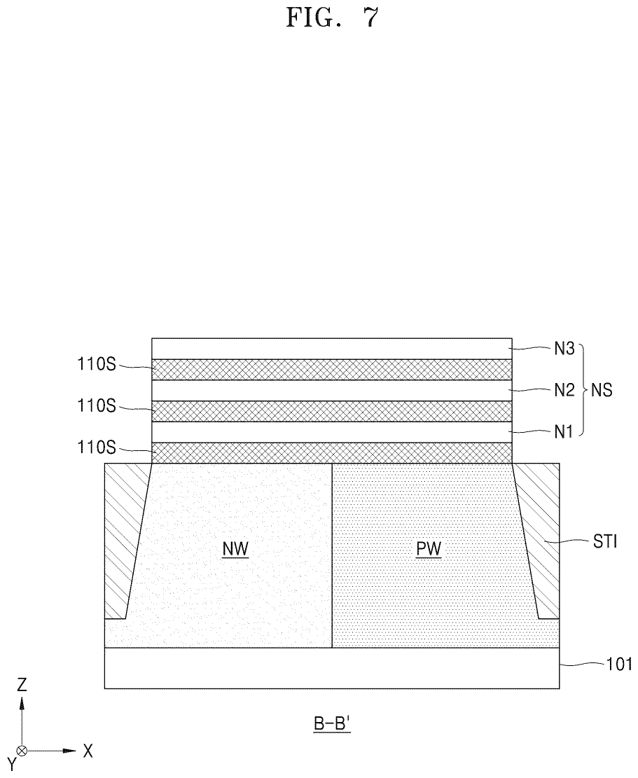

Referring to FIG. 7, portions of the nanosheets NS and the sacrificial dielectric patterns 110S at opposite ends thereof (in the X direction) may be etched to expose the upper surface of the substrate 101. A pair of trench isolations STI may be formed from the exposed upper surface of the substrate 101. The trench isolation STI may be a shallow trench isolation that extends a certain distance from the upper (or top) surface of the substrate 101 into the first well region NW and the second well region PW. The trench isolation STI may be a double-layer structure including an interface layer and a buried dielectric layer.

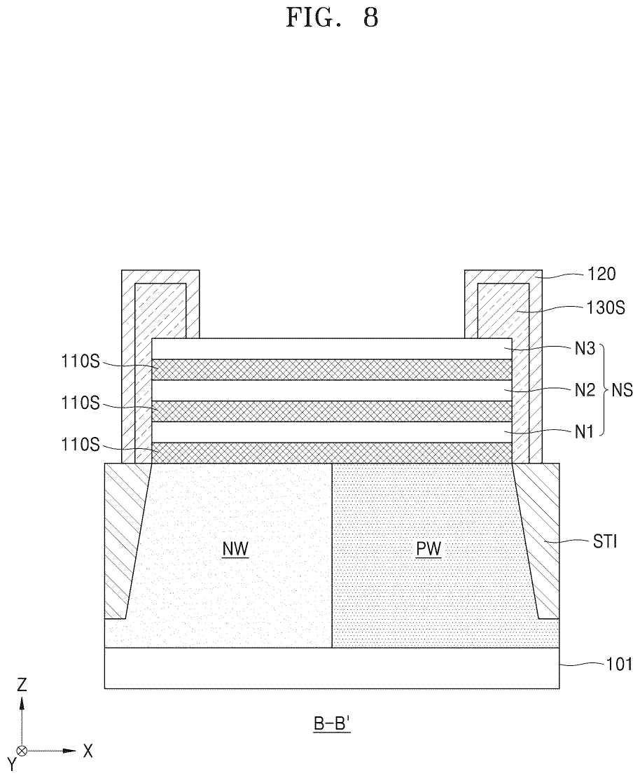

Referring to FIG. 8, a sacrificial material film 130S surrounding opposite ends of the nanosheets NS and sacrificial dielectric patterns 110S in the first horizontal direction (X direction), and a gate spacer 120 surrounding (or covering) the sacrificial material film 130S may be formed. In some example embodiments, the sacrificial material film 130S may include polysilicon, but is not limited thereto and may include other suitable materials. In some example embodiments, the gate spacer 120 may include silicon oxide, silicon nitride, silicon oxynitride, silicon carbonitride, silicon oxycarbonitride, or any combination thereof.

Referring to FIG. 9, impurities of different conductivity types may be implanted into the nanosheets NS and the sacrificial dielectric patterns 110S using suitable ion implantation processes (IIP). First, the same conductivity type impurity (e.g., n-type impurity) as the first well region NW may be implanted into the nanosheets NS, the sacrificial dielectric patterns 110S, and the first well region NW. Next, the same conductivity type impurity (e.g., p-type impurity) as the second well region PW may be implanted into the nanosheets NS, the sacrificial dielectric patterns 110S, and the second well region PW. In some example embodiments, the impurities may be implanted in an entire thickness (Z direction) of the nanosheets NS and the sacrificial dielectric patterns 110S, and the impurities may be implanted in the first well region NW and second well region PW to a certain depth from the upper surfaces of the first well region NW and second well region PW. The implantation may be performed using any suitable ion implantation process (IIP) and a detailed description thereof will be omitted here for the sake of brevity.

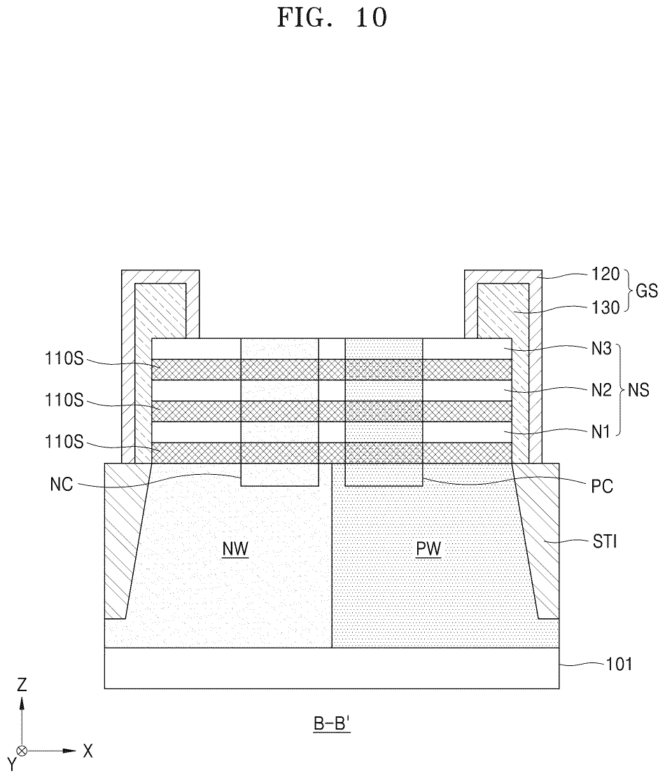

Referring to FIG. 10, a first impurity conductive portion NC and a second impurity conductive portion PC may be formed after a heat treatment process. The first impurity region NC and the second impurity region PC may electrically connect the first well region NW and the second well region PW to the contacts CT. In some example embodiments, upper (or top) surfaces of the first impurity conductive portion NC and the second impurity conductive portion PC may be substantially at a same level as the upper (or top) surface of the third nanosheet N3. The lowermost (or bottom) surfaces of the first impurity conductive portion NC and the second impurity conductive portion PC may be located in the respective first well region NW and the second well region PW.

Next, the sacrificial material film 130S may be removed (see FIG. 9), and a gate electrode 130 may be formed in the location where the sacrificial material film 130S is removed (see FIG. 9). In some example embodiments, the gate electrode 130 may include doped polysilicon, metal, conductive metal nitride, conductive metal carbide, conductive metal silicide, or any combination thereof. A pair of gate structures GS surrounding both ends of the nanosheets NS and the sacrificial dielectric patterns 110S, respectively, may thus be formed.

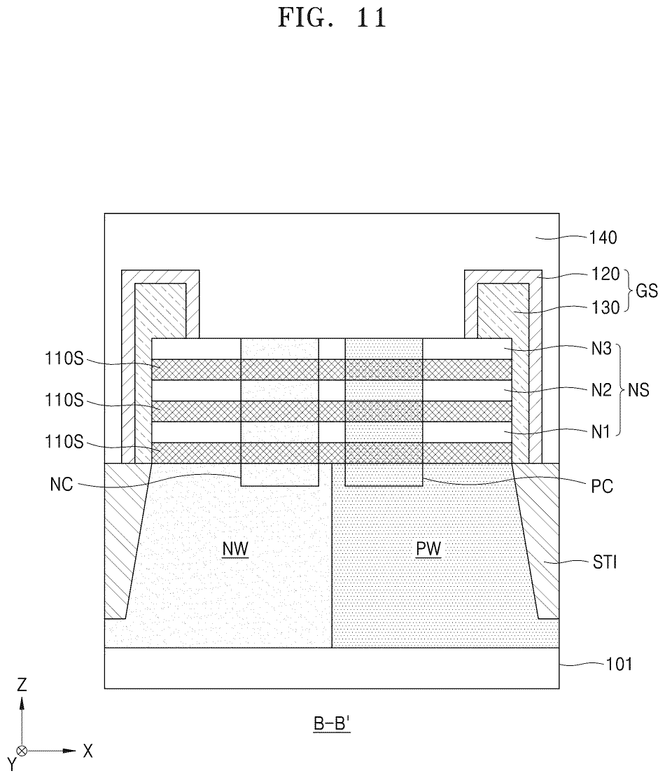

Referring to FIG. 11, an inter-gate dielectric layer 140 may be deposited to cover the pair of gate structures GS and the nanosheets NS. In some example embodiments, the inter-gate dielectric layer 140 may include silicon oxide, silicon nitride, silicon oxynitride, silicon carbonitride, silicon oxycarbonitride, or any combination thereof.

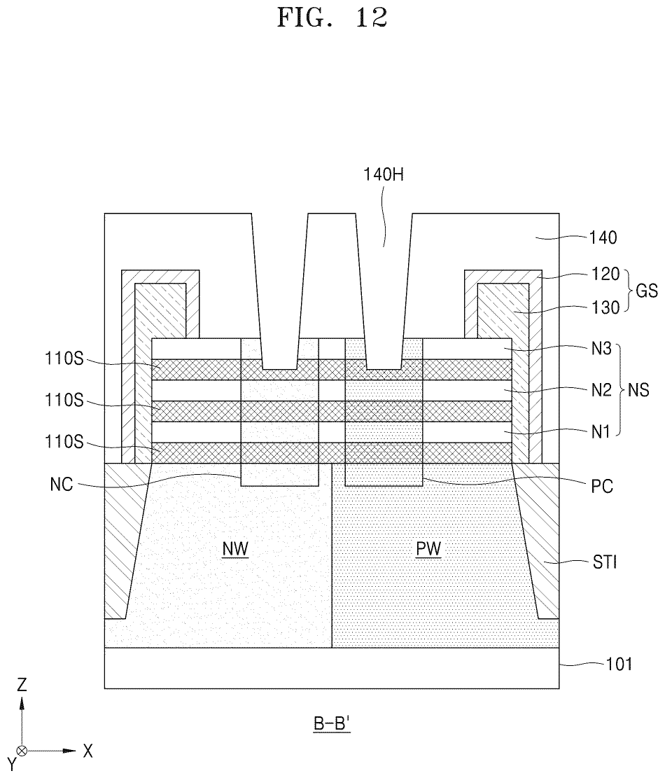

Referring to FIG. 12, contact holes 140H may be formed in the inter-gate dielectric layer 140 to expose the first impurity conductive portion NC and the second impurity conductive portion PC.

In some example embodiments, the contact holes 140H may be formed by etching the inter-gate dielectric layer 140, the third nanosheet N3 (or the topmost nanosheet of the plurality of nanosheets), and upper portions of the sacrificial dielectric patterns 110S using a photo and etching process.

In some example embodiments, the topmost sacrificial dielectric pattern 110S may not be etched and the contact holes 140H may be formed by etching the inter-gate dielectric layer 140 and upper portions of the third nanosheet N3 using, for example, a photo and etching process. The lowermost (or bottom) surface of the contact holes 140H may thus be located within the third nanosheet N3 (or the topmost nanosheet of the plurality of nanosheets).

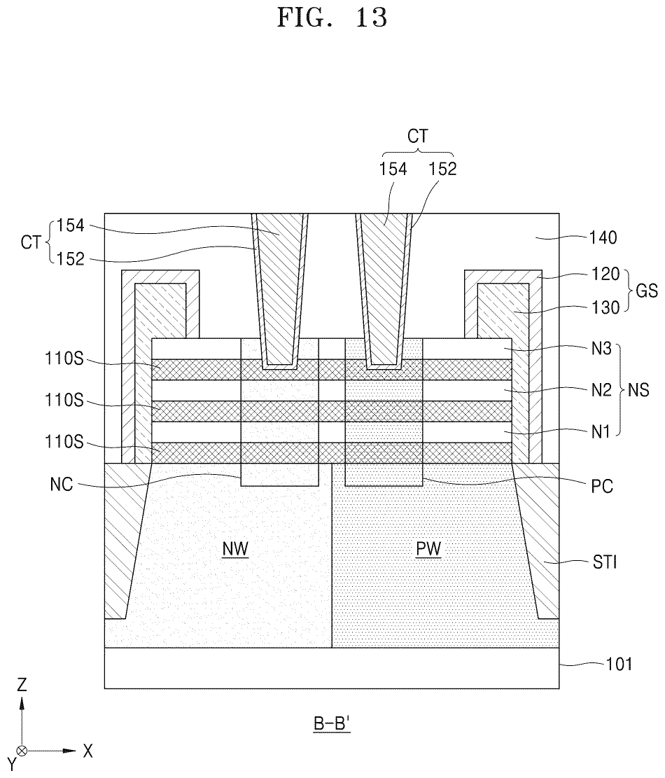

Referring to FIG. 13, the contact holes 140H (see FIG. 12) may be filled to form the contacts CT. The contacts CT may include a first contact electrically connected to the first impurity region NC and a second contact electrically connected to the second impurity region PC. The contacts CT may extend in the vertical direction (Z direction) and may be disposed between the pair of gate structures GS in the first horizontal direction (X direction). In some example embodiments, each of the contacts CT may be a double-layer structure including a metal buried layer 154 and a metal barrier film 152 surrounding side and bottom surfaces of the metal buried layer 154. The metal barrier film 152 may be deposited on the third nanosheet N3 and the sacrificial dielectric patterns 110S that are exposed in the contact holes 140H, and the metal buried layer 154 may be disposed on the metal barrier film 152 to cover the metal barrier film 152. In some example embodiments, where the top sacrificial dielectric pattern 110S is not etched, the metal barrier film 152 may be deposited only on the third nanosheet N3.

In some example embodiments, the metal barrier film 152 may be omitted, and one or more contacts CT may be formed as a single layer structure including the metal buried layer 154 that contacts the third nanosheet N3 and the sacrificial dielectric patterns 110S. In some example embodiments, where the top sacrificial dielectric pattern 110S is not etched, the metal buried layer 154 may be deposited only on the third nanosheet N3.

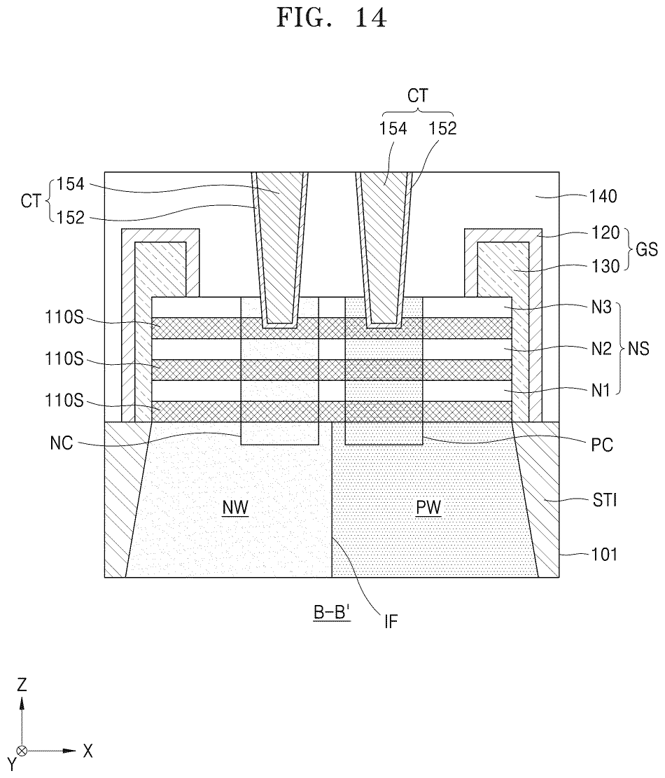

Referring to FIG. 14, a bottom surface removal process may be performed to reduce a thickness of the substrate 101. The bottom surface removal process to reduce the thickness of the substrate 101 may include a process of exposing the bottom surface of a pair of trench isolations STI by alternately performing a grinding process and a wet etching process. Accordingly, after a portion of the substrate 101 is removed, the lower (or bottom) surface of the substrate 101 may be substantially at a same level as the lower (or bottom) surface of the first well region NW and the lower (or bottom) surface of the second well region PW.

A BSPDN (FIG. 1B) may further be formed on the lower surface of the substrate 101, and a connection structure such as a via contact for connecting the BSPDN and a lateral diode (e.g., lateral diode including the first well region NW and the second well region PW) may be further formed.

The semiconductor device 10 manufactured according to some example embodiments disclosed in FIGS. 5-14 and having the first impurity conductive portion NC and the second impurity conductive portion PC in a lateral PN junction diode has an improved performance and reliability.

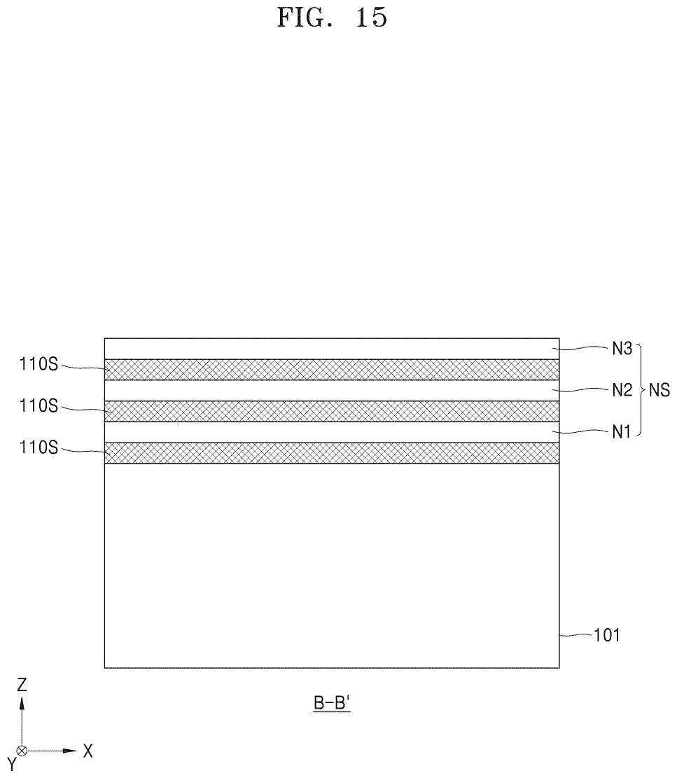

FIGS. 15 to 23 are cross-sectional views illustrating operations in a method of manufacturing a semiconductor device, according to some example embodiments. It is understood that additional operations can be provided before, during, and after the operations in FIGS. 15-23, and some of the operations described below can be replaced or eliminated, for additional embodiments of the method. The order of the operations/processes may be interchangeable, or two or more operations can be performed simultaneously.

Referring to FIG. 15, a substrate 101 having a first surface and a second surface opposite the first surface may be prepared. The first surface may correspond to an upper surface (or active surface) and the second surface may correspond to a lower surface (or inactive surface). A plurality of nanosheets NS and sacrificial dielectric patterns 110S may be alternately stacked in the vertical direction (Z direction) on the upper surface of the substrate 101. Each of the nanosheet NS may be or include a semiconductor pattern. In some example embodiments, the nanosheets NS may include a first nanosheet N1, a second nanosheet N2, and a third nanosheet N3 spaced apart from each other in the vertical direction (Z direction). The sacrificial dielectric patterns 110S may be formed between the nanosheets NS. In some example embodiments, a width (or length) of the nanosheets NS in the first horizontal direction (X direction) and a width (or length) of the sacrificial dielectric patterns 110S in the first horizontal direction (X direction) may be substantially equal.

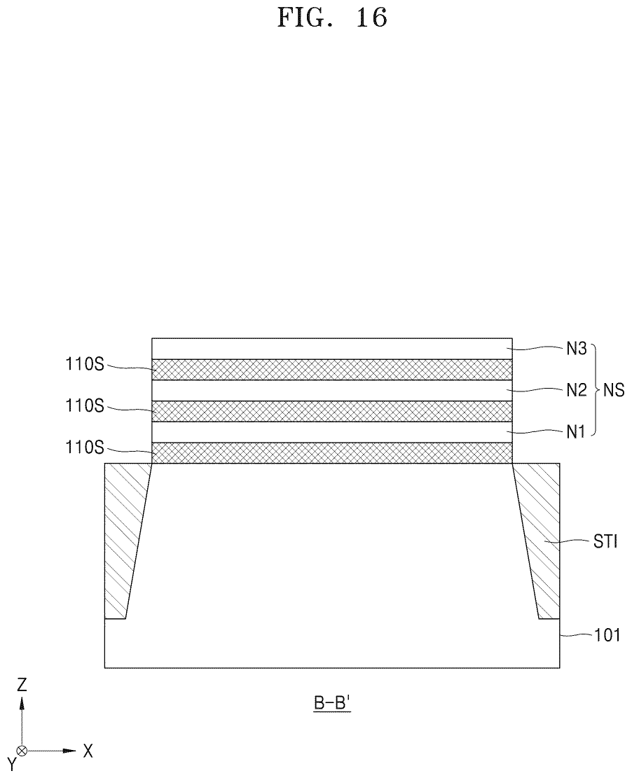

Referring to FIG. 16, portions of the nanosheets NS and the sacrificial dielectric patterns 110S at opposite ends thereof (in the X direction) may be etched to expose the upper surface of the substrate 101. A pair of trench isolations STI may be formed from the exposed upper surface of the substrate 101. The trench isolation STI may be a shallow trench isolation that extends a certain distance from the upper (or top) surface of the substrate 101 into the substrate 101. The trench isolation STI may be formed to have a double-layer structure including an interface layer and a buried dielectric layer.

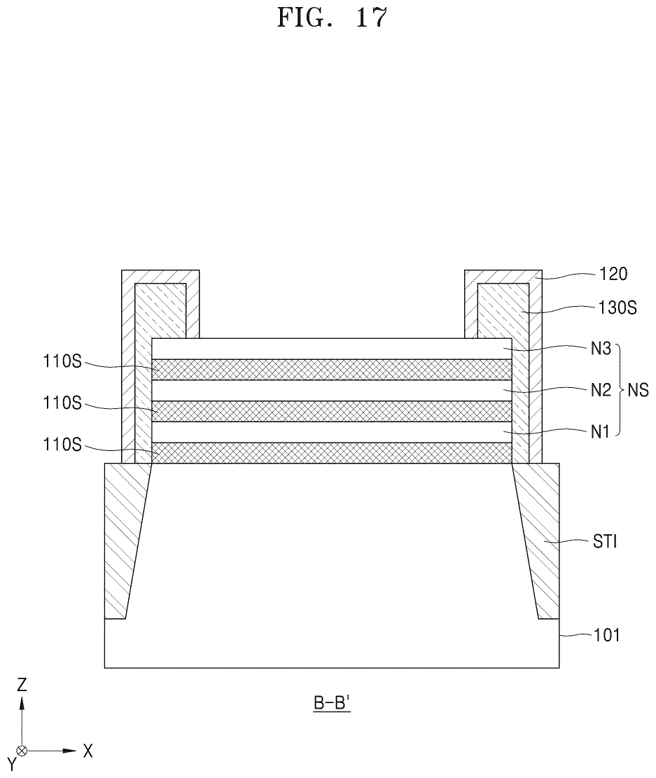

Referring to FIG. 17, a sacrificial material film 130S surrounding opposite ends of the nanosheets NS and sacrificial dielectric patterns 110S in the first horizontal direction (X direction), and a gate spacer 120 surrounding (or covering) the sacrificial material film 130S may be formed. In some example embodiments, the sacrificial material film 130S may include polysilicon, but is not limited thereto. In some example embodiments, the gate spacer 120 may include silicon oxide, silicon nitride, silicon oxynitride, silicon carbonitride, silicon oxycarbonitride, or any combination thereof.

Referring to FIG. 18, impurities of different conductivity types may be implanted into the nanosheets NS, the sacrificial dielectric patterns 110S, and the substrate 101 using a suitable ion implantation process.

First, a first conductivity type impurity (e.g., n-type impurity) may be implanted into the plurality of nanosheets NS, the sacrificial dielectric patterns 110S, and portions of the substrate 101. Next, a second conductivity type impurity (e.g., p-type impurity) may be implanted into the plurality of nanosheets NS, sacrificial dielectric patterns 110S, and other portions of the substrate 101. In some example embodiments, the impurities may be implanted in an entire thickness (Z direction) of the plurality of nanosheets NS and the sacrificial dielectric patterns 110S, and the impurities may be implanted to a certain depth from the upper surface of the substrate 101. The first conductivity type impurity (e.g., n-type impurity) and the second conductivity type impurity (e.g., p-type impurity) may be implanted in locations adjacent to each other.

The implantation may be performed using any suitable ion implantation process (IIP) and a detailed description thereof will be omitted here for the sake of brevity.

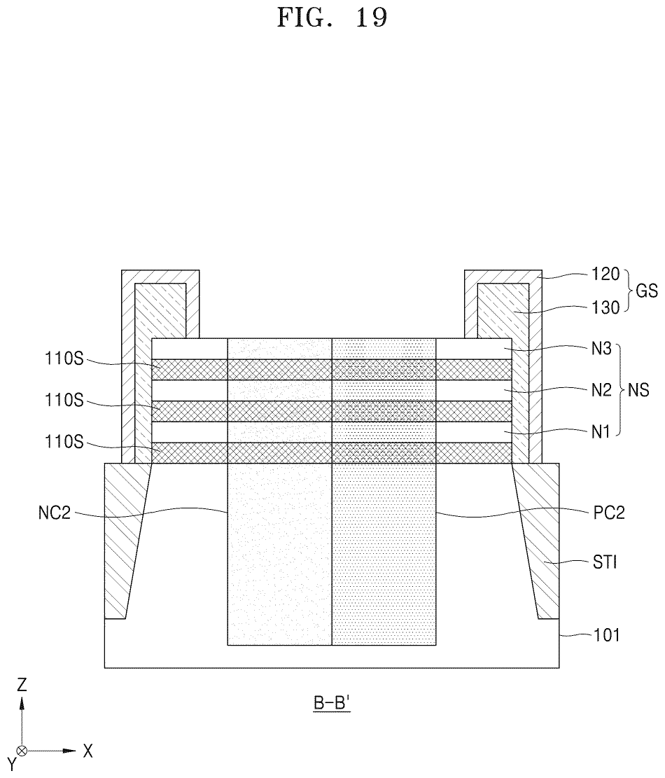

Referring to FIG. 19, a first impurity region NC2 and a second impurity region PC2 may be formed through a heat treatment process on the implanted impurities of different conductivity types. In some example embodiments, upper surfaces of the first impurity region NC2 and the second impurity region PC2 may be at substantially a same level as the upper surface of the third nanosheet N3 (or the topmost nanosheet), and the lowermost (or bottom) surfaces of the first impurity region NC2 and the second impurity region PC2 may be spaced (e.g., a gap is defined) from the bottom surface of substrate 101. Stated otherwise, the lowermost (or bottom) surfaces of the first impurity region NC2 and the second impurity region PC2 may be located within the substrate 101.

Next, the sacrificial material film 130S (FIG. 18) may be removed, and a gate electrode 130 may be formed. In some example embodiments, the gate electrode 130 may include doped polysilicon, metal, conductive metal nitride, conductive metal carbide, conductive metal silicide, or any combination thereof.

As a result, a pair of gate structures GS surrounding both ends of the nanosheets NS and the sacrificial dielectric patterns 110S, respectively, may be formed.

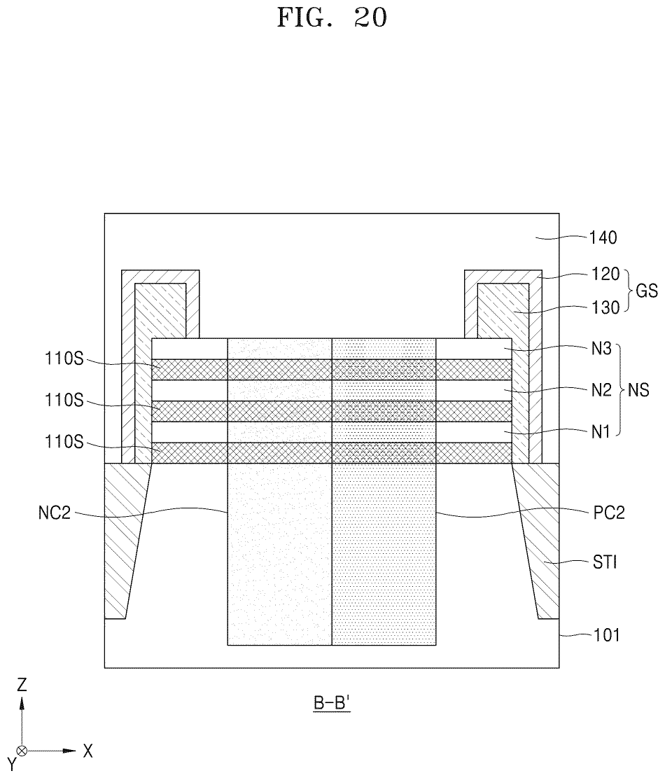

Referring to FIG. 20, an inter-gate dielectric layer 140 may be formed to cover the pair of gate structures GS and plurality of nanosheets NS. In some example embodiments, the inter-gate dielectric layer 140 may include silicon oxide, silicon nitride, silicon oxynitride, silicon carbonitride, silicon oxycarbonitride, or any combination thereof.

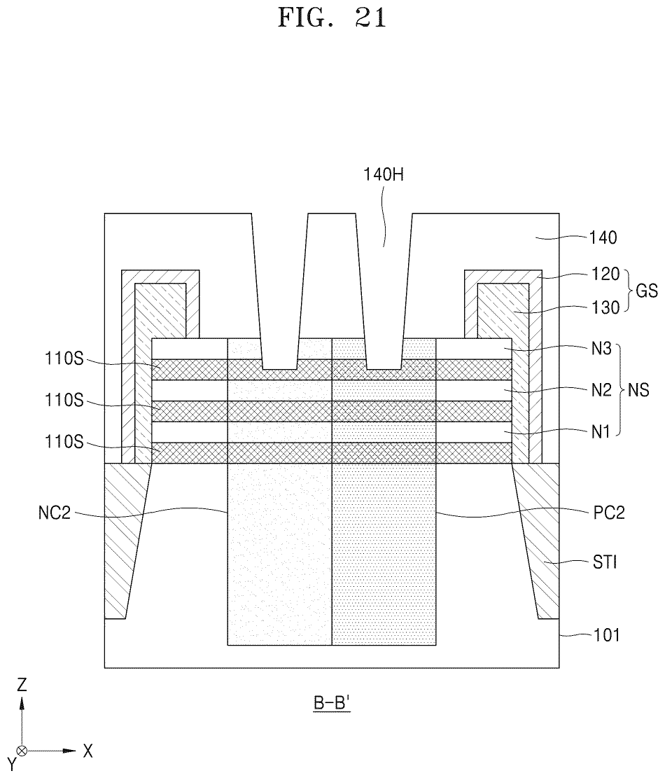

Referring to FIG. 21, contact holes 140H may be formed to expose upper portions of the first impurity region NC2 and the second impurity region PC2.

In some example embodiments, the contact holes 140H may be formed by etching the inter-gate dielectric layer 140, the third nanosheet N3, and a portion of the uppermost layer of the sacrificial dielectric patterns 110S using a photo and etching process.

In some example embodiments, the contact holes 140H may be formed by etching a portion of the inter-gate dielectric layer 140 and the third nanosheet N3 using a photo and etching process, and the portion of the uppermost sacrificial dielectric patterns 110S may not be etched. As a result, the bottom surface of the contact holes 140H may be located within the third nanosheet N3 instead of being located in the uppermost sacrificial dielectric patterns 110S.

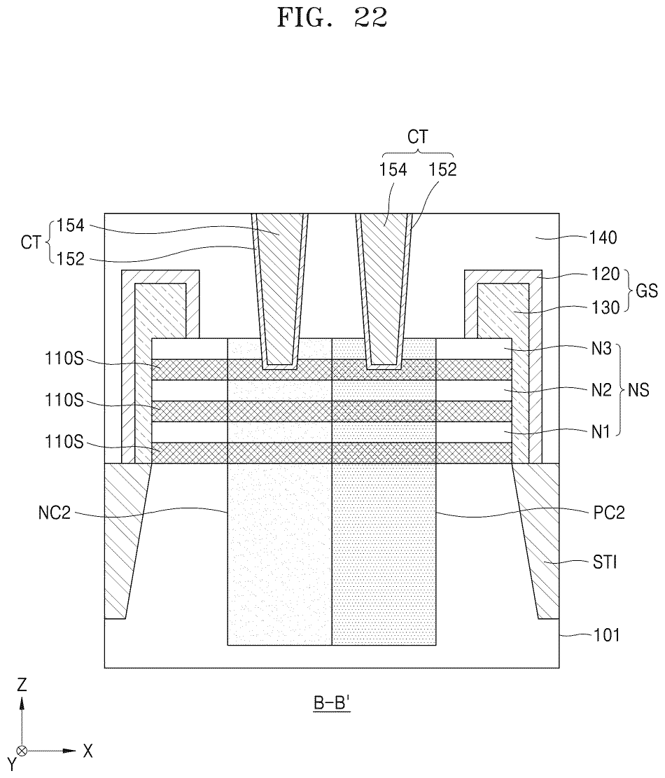

Referring to FIG. 22, contacts CT that fill the contact holes 140H (see FIG. 21) may be formed. The contacts CT may include a first contact electrically connected to the first impurity region NC2 and a second contact electrically connected to the second impurity region PC2. The contacts CT may be disposed between the pair of gate structures GS in the first horizontal direction (X direction).

In some example embodiments, each of the contacts CT may be a double-layer structure including a metal buried layer 154 and a metal barrier film 152 surrounding side and bottom surfaces of the metal buried layer 154. The metal barrier film 152 may be deposited on the third nanosheet N3 and the sacrificial dielectric patterns 110S that are exposed in the contact holes 140H, and the metal buried layer 154 may be deposited on the metal barrier film 152 to cover the metal barrier film 152. In some example embodiments, the metal barrier film 152 may be omitted, and one or more contacts CT may be formed as a single layer structure including the metal buried layer 154 that contacts the third nanosheet N3 and the sacrificial dielectric patterns 110S. In some example embodiments, where the top sacrificial dielectric pattern 110S is not etched, the metal buried layer 154 may be deposited only on the third nanosheet N3.

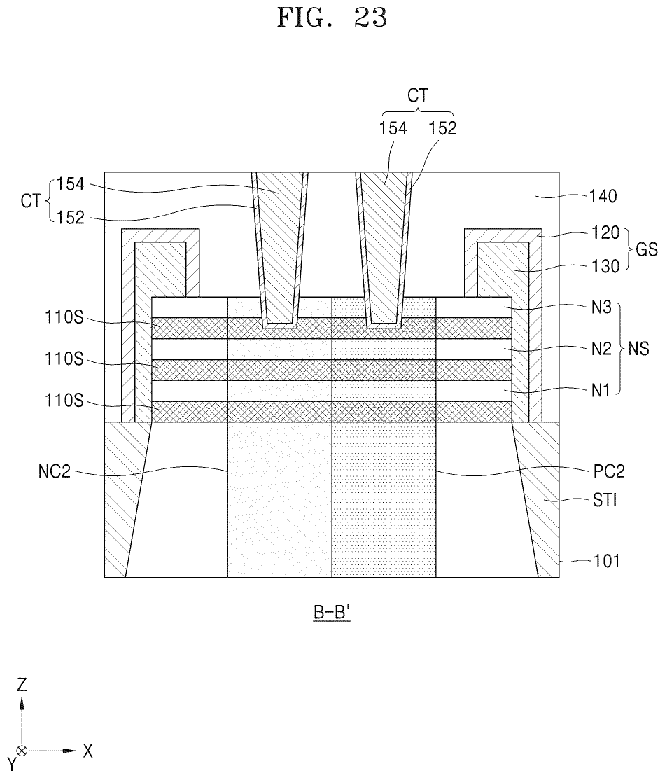

Referring to FIG. 23, a bottom surface removal process may be performed to reduce a thickness of the substrate 101. The bottom surface removal process to reduce the thickness of the substrate 101 may include a process of exposing the bottom surface of a pair of trench isolations STI by alternately performing a grinding process and a wet etching process. Accordingly, after a portion of the substrate 101 is removed, the lower (or bottom) surface of the substrate 101 may be substantially at a same level as the lower (or bottom) surface of the first impurity region NC2 and the lower (or bottom) surface of the second impurity region PC2.

A BSPDN (FIG. 2B) may further be formed on the lower surface of the substrate 101, and a connection structure such as a via contact for connecting the BSPDN and a lateral diode (e.g., lateral diode including the first impurity region NC2 and second impurity region PC2) may be further formed.

The semiconductor device 20 manufactured according to some example embodiments disclosed in FIGS. 15-23 and having the first impurity region NC2 and the second impurity region PC2 in a lateral PN junction has an improved performance and reliability.

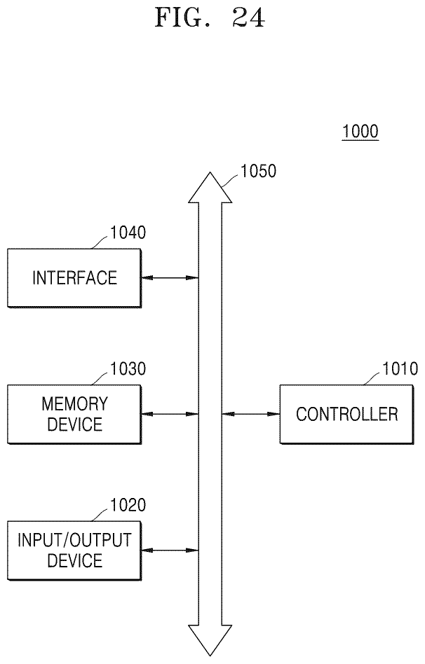

FIG. 24 is a configuration of a system 1000 including a semiconductor device according to some example embodiments discussed above. Referring to FIG. 24, the system 1000 may include a controller 1010, an input/output device 1020, a memory device 1030, an interface 1040, and a bus 1050. The system 1000 may be a mobile system or a system that transmits or receives information. In some example embodiments, the mobile system may be a portable computer, a web tablet, a mobile phone, a digital music player, a memory card, or the like. The controller 1010 is configured to execute programming code stored in the memory device 1030 for performing the various operations of the system 1000. The controller 1010 is any electronic circuitry including, but not limited to, a microprocessor, a digital signal processor, a microcontroller, or a similar device.

The input/output device 1020 may be used to input or output data of the system 1000. The system 1000 may be connected to an external device, for example, a personal computer or a network, using the input/output device 1020, and may exchange data with the external device. The input/output device 1020 may be, for example, a touch screen, a touch pad, a keyboard, or a display.

The memory device 1030 may store data for the operation of the controller 1010 or store data processed by the controller 1010. The memory device 1030 may include any one of the semiconductor devices 10, 20, 30, 40, and 50 according to some example embodiments described above.

The interface 1040 may be a data transmission path between the system 1000 and an external device. The controller 1010 is configured to send and receive data using the interface 1040. The interface 1040 may be configured to use any suitable type of communication protocol as would be appreciated by one of ordinary skill in the art. The controller 1010, the input/output device 1020, the memory device 1030, and the interface 1040 may communicate with each other via the bus 1050.

While several embodiments have been provided in the present disclosure, it should be understood that the disclosed systems and methods might be embodied in many other specific forms without departing from the spirit or scope of the present disclosure. The present examples are to be considered as illustrative and not restrictive, and the intention is not to be limited to the details given herein. For example, the various elements or components may be combined or integrated in another system or certain features may be omitted, or not implemented.

In addition, techniques, systems, subsystems, and methods described and illustrated in the various embodiments as discrete or separate may be combined or integrated with other systems, modules, techniques, or methods without departing from the scope of the present disclosure. Other items shown or discussed as coupled or directly coupled or communicating with each other may be indirectly coupled or communicating through some interface, device, or intermediate component whether electrically, mechanically, or otherwise. Other examples of changes, substitutions, and alterations are ascertainable by one skilled in the art and could be made without departing from the spirit and scope disclosed herein.

What is claimed is:

1. A semiconductor device comprising:
a substrate having a first surface and a second surface opposite the first surface;
a pair of trench isolations penetrating through the substrate;
a first well region and a second well region in a first horizontal direction in the substrate between the pair of trench isolations, the first well region and the second well region contacting each other;
a plurality of nanosheets and a plurality of sacrificial dielectric patterns alternately stacked in a vertical direction on the first well region and the second well region;
a first inactive gate structure overlapping first ends of the plurality of nanosheets and the plurality of sacrificial dielectric patterns in a second horizontal direction perpendicular to the first horizontal direction;
a second inactive gate structure overlapping second ends of the plurality of nanosheets and the plurality of sacrificial dielectric patterns in the second horizontal direction, the first ends and the second ends being opposite to each other in the first horizontal direction;
a first impurity region on the first well region and connected thereto, the first impurity region penetrating through the plurality of nanosheets and the plurality of sacrificial dielectric patterns in the vertical direction;
a second impurity region on the second well region and connected thereto, the second impurity region penetrating through the plurality of nanosheets and the plurality of sacrificial dielectric patterns in the vertical direction;
a first contact connected to the first impurity region; and
a second contact connected to the second impurity region.

2. The semiconductor device of claim 1, wherein
the first well region and the second well region contact in the first horizontal direction and define an interface therebetween, and
the first inactive gate structure and the second inactive gate structure are vertically offset from the interface.

3. The semiconductor device of claim 2, wherein
the first contact and the second contact are between the first inactive gate structure and the second inactive gate structure in the first horizontal direction.

4. The semiconductor device of claim 1, wherein
the first impurity region and the second impurity region are regions in the plurality of nanosheets and the plurality of sacrificial dielectric patterns which are doped with impurities of different conductivity types.

5. The semiconductor device of claim 4, wherein
the plurality of nanosheets are semiconductor patterns, and the plurality of sacrificial dielectric patterns are dielectric patterns.

6. The semiconductor device of claim 4, wherein
uppermost surfaces of the first impurity region and the second impurity region are at a same level as an uppermost surface of the plurality of nanosheets, and
lowermost surfaces of the first impurity region and the second impurity region are between the first surface and the second surface of the substrate.

7. The semiconductor device of claim 1, wherein
a length of each of the plurality of nanosheets in the first horizontal direction and a length of each of the plurality of sacrificial dielectric patterns in the first horizontal direction are same.

8. The semiconductor device of claim 1, wherein
the first well region and the second well region are regions in the substrate which are doped with impurities of different conductivity types, and
the first well region and the second well region contact each other to form a lateral diode.

9. The semiconductor device of claim 8, wherein
upper surfaces of the first well region and the second well region are at a same level as the first surface of the substrate, and
lowermost surfaces of the first well region and the second well region are at a same level as the second surface of the substrate.

10. The semiconductor device of claim 1, wherein
the first impurity region and the first well region include impurities of a first conductivity type,
the second impurity region and the second well region include impurities of a second conductivity type, and
the impurities of the first conductivity type and the impurities of the second conductivity type are of opposite conductivity types.

11. A semiconductor device comprising:
a substrate having a first surface and a second surface opposite the first surface;
a pair of trench isolations penetrating the substrate and spaced from each other in a first horizontal direction;
a plurality of nanosheets and a plurality of sacrificial dielectric patterns alternately stacked in a vertical direction on the substrate between the pair of trench isolations;
a first inactive gate structure overlapping first ends of the plurality of nanosheets and the plurality of sacrificial dielectric patterns in a second horizontal direction perpendicular to the first horizontal direction;
a second inactive gate structure overlapping second ends of the plurality of nanosheets and the plurality of sacrificial dielectric patterns in the second horizontal direction, the first ends and the second ends being opposite to each other in the first horizontal direction;
a first impurity region penetrating the substrate, the plurality of nanosheets, and the plurality of sacrificial dielectric patterns in the vertical direction;
a second impurity region penetrating the substrate, the plurality of nanosheets, and the plurality of sacrificial dielectric patterns in the vertical direction;
a first contact connected to the first impurity region; and
a second contact connected to the second impurity region.

12. The semiconductor device of claim 11, wherein
the first impurity region and the second impurity region contact in the first horizontal direction and define an interface therebetween,
the first inactive gate structure and the second inactive gate structure are vertically offset from the interface, and
the first contact and the second contact are between the pair of inactive gate structures in the first horizontal direction.

13. The semiconductor device of claim 11, further comprising:
a first well region and a second well region in the first horizontal direction in the substrate between the pair of trench isolations, wherein the first well region and the second well region contact each other.

14. The semiconductor device of claim 11, wherein
the first impurity region and the second impurity region are doped with impurities of different conductivity types, and
the first impurity region and the second impurity region contact each other to form a lateral diode.

15. The semiconductor device of claim 11, wherein
uppermost surfaces of the first impurity region and the second impurity region are at a same level as an uppermost surface of the plurality of nanosheets, and
lowermost surfaces of the first impurity region and the second impurity region are at a same level as the second surface of the substrate.

16. The semiconductor device of claim 11, wherein
a length of each nanosheet of the plurality of nanosheets in the first horizontal direction and a length of each sacrificial dielectric pattern of the plurality of sacrificial dielectric patterns in the first horizontal direction are same.

17. A semiconductor device comprising:
a substrate having a first surface and a second surface opposite the first surface;
a pair of trench isolations penetrating the substrate;
a first well region and a second well region in a first horizontal direction in the substrate between the pair of trench isolations, the first well region and the second well region contacting each other;
a plurality of nanosheets and a plurality of sacrificial dielectric patterns alternately stacked in a vertical direction on the first well region and the second well region;
a first impurity region penetrating through the plurality of nanosheets and the plurality of sacrificial dielectric patterns in the vertical direction on the first well region, the first impurity region contacting the first well region;
a second impurity region penetrating through the plurality of nanosheets and the plurality of sacrificial dielectric patterns in the vertical direction on the second well region, the second impurity region contacting the second well region;
a first contact connected to the first impurity region;
a second contact connected to the second impurity region; and
a back side power distribution network beneath the second surface of the substrate.

18. The semiconductor device of claim 17, further comprising:
a plurality of first contacts and a plurality of second contacts in the first horizontal direction.

19. The semiconductor device of claim 17, wherein
the plurality of nanosheets and the plurality of sacrificial dielectric patterns constitute multiple groups, and
the multiple groups are in a second horizontal direction perpendicular to the first horizontal direction.

20. The semiconductor device of claim 17, wherein
the first well region and the second well region are doped with impurities of different conductivity types, and
wherein the first well region and the second well region contact each other to form a lateral diode.
